(19) United States
(12) Patent Application Publication
(10) Pub. No.: US 2022/0178773 A1
(43) Pub. Date: Jun. 9, 2022

(54) PRESSURE SENSOR AND PACKAGING METHOD THEREOF

(71) Applicant: FATRI UNITED TESTING & CONTROL (QUANZHOU) TECHNOLOGIES CO., LTD., Quanzhou, Fujian (CN)

(72) Inventor: Yongzhong NIE, Xiamen, Fujian (CN)

(73) Assignee: FATRI UNITED TESTING & CONTROL (QUANZHOU) TECHNOLOGIES CO., LTD., Quanzhou, Fujian (CN)

(21) Appl. No.: 17/598,333

(22) PCT Filed: Mar. 24, 2020
(86) PCT No.: PCT/CN2020/080932

§ 371 Date: Sep. 27, 2021

(30) Foreign Application Priority Data
Mar. 27, 2019 (CN) 201910236827.5

(51) Int. Cl. G01L 1/22; B81B 7/00; B81C 1/00

(52) U.S. Cl. CPC G01L 1/2262; B81B 7/007; B81B 2207/095; B81B 2201/0264; B81C 1/00301

(57) ABSTRACT

A pressure sensor and a packaging method thereof. The pressure sensor comprises: a sensitive chip, which comprises a thin-wall part and a supporting part connected to the periphery of the thin-wall part, the supporting part being provided with an electrode; a sealing element, which is fitted over the sensitive chip and partially surrounds together with the sensitive chip to form a sealing cavity, the sealing element being provided with a through hole corresponding to the electrode; a conductive component, which is provided in the through hole in a sealed mode and electrically connected to the electrode, the conductive component and the sealing element being arranged in an insulating mode, and the conductive component comprising a filling part and a leading-out part embedded in the filling part.

### CROSS-REFERENCE TO RELATED APPLICATION

The present application claims the priority of the Chinese patent application 201910236827.5 entitled “Pressure Sensor and Packaging Method Thereof” filed on Mar. 27, 2019, which is incorporated herein by reference in its entirety.

### TECHNICAL FIELD

The present application relates to the technical field of microelectronic mechanical system, and in particular to a pressure sensor and a packaging method thereof.

### BACKGROUND

Thin-film pressure sensors have advantages of good stability, high accuracy, and being suitable for harsh environments, and are widely used in the measurement of pressure parameters in various fields such as national defense, aerospace, industrial production, and automatic control. Among them, the thin-film pressure sensor of absolute pressure type uses the low air pressure in the absolute pressure cavity as the reference air pressure of the zero position of the sensor. The packaging structure of the absolute pressure cavity package will directly affect the size and the environmental adaptability of the sensor.

In the prior art, the packaging method of the metal thin-film pressure sensor basically adopts a packaging method with lead wires. This requires to reserve a larger space for operation and assembly, and thus results in a larger package size.

Therefore, there is an urgent need for a new pressure sensor.

### SUMMARY

The embodiments of the present application provide a pressure sensor, which aims to employ a package without lead wires, reduce a package size and form an absolute pressure packaging structure.

In one aspect, the embodiments of the present application provide a pressure sensor, including: a sensitive chip, including a thin wall portion and a supporting portion connected to an outer periphery of the thin wall portion, and the supporting portion being provided with an electrode; a sealing member, sleeved on the sensitive chip, part of the sealing member defining a sealed cavity together with the sensitive chip, and the sealing member being provided with a through hole corresponding to the electrode; a conductive member, disposed in the through hole in a sealing manner and electrically connected with the electrode, and the conductive member being insulated from the sealing member, wherein the conductive member comprises a filling portion and a lead-out portion embedded in the filling portion.

According to one aspect of the present application, the sealing member comprises a main body and an extending portion connected to the main body, and the main body and the extending portion form an accommodating cavity together, the sealing member is sleeved on the sensitive chip through the accommodating cavity, and the extending portion covers an outer surface of the supporting portion; the main body is provided with a groove, the groove faces the accommodating cavity, and the thin wall portion covers an opening of the groove to form the sealed cavity.

According to one aspect of the present application, the through hole is provided in the main body, and more than four through holes are distributed at intervals on an outer circumferential side of the groove; the through hole is formed in a shape of taper.

According to one aspect of the present application, the supporting portion includes a notch recessed from an outer surface toward an inner surface of the supporting portion, and the extending portion includes a protrusion that matches the notch.

According to one aspect of the present application, the supporting portion includes a stepped structure protruding outwardly at an end away from the thin wall portion.

According to one aspect of the present application, the extending portion abuts against the stepped structure and forms a seal.

According to one aspect of the present application, the filling portion is made of a conductive paste, the lead-out portion is formed as a metal lead pin, and the filling portion is electrically connected with the electrode.

In the embodiments of the present application, the sealing member is sleeved on the sensitive chip, a sealed cavity is formed between the thin wall portion of the sensitive chip and the sealing member, and the conductive member disposed in the through hole of the sealing member is electrically connected to the electrode on the sensitive chip. In the configuration of the pressure sensor, the electrical connection with the electrode is achieved by the conductive member without using the lead wires, which reduces the packaging size of the pressure sensor and realizes absolute pressure packaging.

A further aspect of the embodiments of the present application provides a packaging method of a pressure sensor, the method includes the following steps of: providing a sensitive chip, the sensitive chip including a thin wall portion and a supporting portion connected to an outer periphery of the thin wall portion, the supporting portion being provided with an electrode; sleeving a sealing member on the sensitive chip for pre-assembly processing, part of the sealing member defining a sealed cavity together with the sensitive chip, and the sealing member being provided with a through hole corresponding to the electrode; injecting a filling portion into the through hole and inserting a lead-out portion into the filling portion, and then vacuum sintering and solidifying the filling portion; and absolute pressure packaging the sensitive chip and the sealing member to form a pressure sensor.

According to a further aspect of the present application, the step of sleeving the sealing member on the sensitive chip for pre-assembly processing includes a step of positioning a notch on the sensitive chip relative to a protrusion on the sealing member in an engagement manner for pre-assembly processing.

According to a further aspect of the present application, the step of sealing the sensitive chip and the sealing member includes a step of using an electron beam welding device in which gas in a chamber is replaced with dry argon, and welding and sealing the sensitive chip and the sealing member when a vacuum degree of the electron beam welding device is decreased below a predetermined value.

In the embodiment of the present application, the provided sealing member is sleeved on the sensitive chip, a sealed cavity is formed between the thin wall portion of the sensitive chip and the sealing member, and the conductive member disposed in the through hole on the sealing member is electrically connected to the electrode on the sensitive chip, wherein the filling portion of the conductive member is injected into the through hole and the lead-out portion of the conductive member is inserted into the filling portion, and then the filling portion is vacuumed sintered and solidified; in the packaging method of the pressure sensor, an electrical connection with the electrode is formed by means of the conductive member without using lead wires, which reduces the packaging size of the pressure sensor and realizes the absolute pressure packaging.

### DESCRIPTION OF THE DRAWINGS

The features, advantages, and technical effects of the exemplary embodiments of the present application will be described below with reference to the accompanying drawings.

FIG. 1 is a schematic structural diagram of a pressure sensor according to an embodiment of the present application;

FIG. 2 is a bottom view of a sealing member according to an embodiment of the present application;

FIG. 3 is a three-dimensional schematic diagram of a sealing member according to an embodiment of the present application;

FIG. 4 is a three-dimensional schematic diagram of a sensitive chip according to an embodiment of the present application;

FIG. 5 is a schematic structural diagram of a sensitive chip according to an embodiment of the present application; and

FIG. 6 is a flowchart of a packaging method of a pressure sensor according to an embodiment of the present application.

In the drawings, the drawings are not drawn to actual scale.

Reference numerals:
10-sensitive chip; 11-supporting portion; 12-thin wall portion; 13-notch; 14-electrode; 15-insulating layer; 16-functional layer; 20-sealing member; 21-through hole; 22-extending portion; 23-protrusion; 30-conductive member; 31-filling portion; 32-lead-out portion; 40-sealed cavity.

### DETAILED DESCRIPTION

The implementation of the present application will be described in further detail below in combination with the accompanying drawings and embodiments. The detailed description of the following embodiments and the accompanying drawings are used to exemplarily illustrate the principle of the present application, but cannot be used to limit the scope of the present application, that is, the present application is not limited to the described embodiments.

The features and exemplary embodiments of various aspects of the present application will be described in detail below. In the following detailed description, many specific details are proposed in order to provide a comprehensive understanding of the present application. However, it is obvious to the person skilled in the art that the present application can be implemented without some of these specific details. The following description of the embodiments is only to provide a better understanding of the present application by showing examples of the present application. In the accompanying drawings and the following description, at least part of well-known structures and technologies are not shown in order to avoid unnecessary blurring of the present application; and, for clarity, size of some structures may be exaggerated. In addition, the features, structures or characteristics described below may be combined into one or more embodiments in any suitable manner.

The orientation words appearing in the following description are all directions shown in the drawings, and are not intended to limit the specific structures of the embodiments of the present application. In the description of the present application, it should also be noted that, unless otherwise clearly specified and limited, the terms “installation” and “connection” should be understood in a broad sense, for example, it can be a fixed connection or a detachable connection, or an integral connection, and it can be direct connection or indirect connection. For the person skilled in the art, the specific meaning of the above-mentioned terms in the present application can be understood according to specific circumstances.

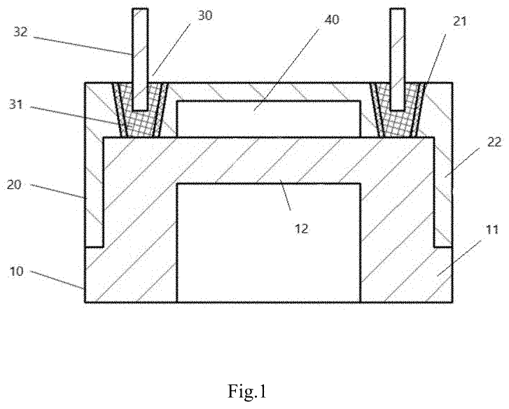

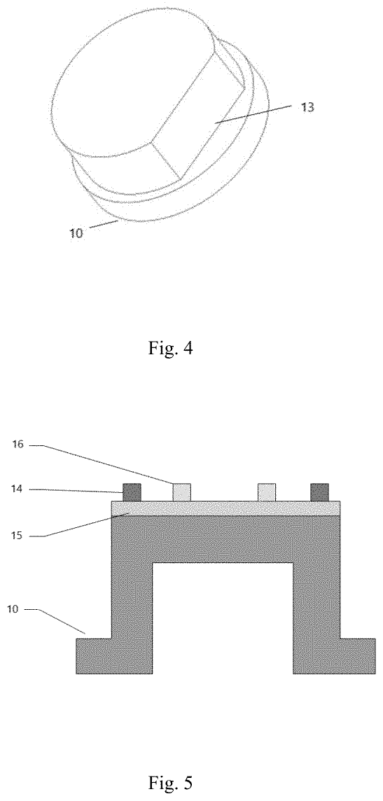

In order to better understand the present application, the pressure sensor according to the embodiments of the present application will be described in detail below with reference to FIGS. 1 to 5.

FIG. 1 shows a pressure sensor provided by an embodiment of the present application, and the pressure sensor includes: a sensitive chip 10, a sealing member 20, and a conductive member 30. The sensitive chip 10 includes a thin wall portion 12 and a supporting portion 11 connected to an outer periphery of the thin wall portion 12, and the supporting portion 11 is provided with an electrode. The sealing member 20 is sleeved on the sensitive chip 10, part of the sealing member 20 defines a sealed cavity 40 together with the sensitive chip 10, and the sealing member 20 is provided with a through hole 21 corresponding to the electrode. The conductive member 30 is disposed in the through hole 21 and electrically connected with the electrode, and the conductive member 30 and the sealing member 20 are insulated from each other, wherein the conductive member 30 includes a filling portion 31 and a lead-out portion 32 embedded in the filling portion 31.

The shape of the thin wall portion 12 is not specifically limited, and the thin wall portion 12 may be formed in a circular sheet shape, a square sheet shape, an oval sheet shape, etc., and preferably in a circular sheet shape. The supporting portion 11 is connected to an outer periphery of the thin wall portion 12; for example, the supporting portion 11 may be formed in a shape of cylinder, and the thin wall portion 12 may be formed in the circular sheet shape; and as shown in FIG. 1, the thin wall portion 12 is located at one end of the cylinder of the supporting portion 11 and completely matches and contacts an inner wall profile of the cylinder at the one end, and forms a cavity with an opening facing downward (that is, the direction as shown in the figure) together with the supporting portion 11. In a preferred example, the thin wall portion 12 and the supporting portion 11 are integrally formed into a shape of cup.

The electrode is provided on an end surface of the supporting portion 11 where the thin wall portion 12 is located, the electrode is insulated from the supporting portion 11, and optionally, an insulating layer is disposed between the electrode and the supporting portion 11.

In the conductive member 30, either one of the filling portion 31 and the lead-out portion 32 is electrically connected to the electrode, or both of the filling portion 31 and the lead-out portion 32 are electrically connected to the electrode. In one example, the lead-out portion 32 is partially embedded in the filling portion 31 with the remaining part exposed, the filling portion 31 is electrically connected to the electrode, and an electrical signal is transmitted to the filling portion 31 via the electrode, and then transmitted to the lead-out portion 32, and finally transmitted to other structures via other mediums such as wires.

The shape and number of the lead-out portion 32 are not limited. Corresponding to one conductive member 30, the lead-out portion 32 may be cylindrical, needle-shaped, flat, etc., may be a single integral structure or an assembled structure composed of several parts, and further may be a plurality of separate structures arranged at intervals, and all such structures fall within the protection scope of the present application. The shape and properties of the filling portion 31 are also not limited; before the embedded lead-out portion 32 is fixed to the through hole 21, the filling portion 31 may be in a powder or a fluid form, and after the lead-out portion 32 is fixed to the through hole 21, the filling portion 31 may be in a solid form.

In the embodiment of the present application, the sealing member 20 is sleeved on the sensitive chip 10, a sealed cavity is formed between the thin wall portion 12 of the sensitive chip 10 and the sealing member 20, and the conductive member 30 disposed in the through hole 21 of the sealing member 20 is electrically connected to the electrode on the sensitive chip 10. In the configuration of the pressure sensor, the electrical connection with the electrode is achieved by the conductive member 30, without using lead wires and corresponding adapting plates, which reduces the packaging size of the pressure sensor, realizes absolute pressure packaging, and also avoids risk of breakage of lead wires due to the soft material in the extreme shock and vibration environment.

In some alternative embodiments, referring to FIGS. 1-3 at the same time, the sealing member 20 includes a main body and an extending portion 22 connected to the main body, the main body and the extending portion 22 form an accommodating cavity together, and the sealing member 20 is sleeved on the sensitive chip 10 through the accommodating cavity, with the extending portion 22 covering an outer surface of the supporting portion 11; as shown in FIG. 1, an inner transversal profile enclosed by the extending portion 22 matches and corresponds to an outer transversal profile of the sensitive chip 10, and an inner surface of the accommodating cavity of the main body can be joined to an upper surface of the sensitive chip 10. The main body is provided with a groove, the groove faces the accommodating cavity, and the thin wall portion 12 covers an opening of the groove to form the sealed cavity 40. Optionally, the groove has a transversal profile consistent with and corresponding to a transversal profile of the thin wall portion 12, and preferably, both of them are circular.

It is understandable that the main body and the extending portion 22 may be integrally formed, or may be formed into two separate structures, which are assembled into one integrity by bonding, welding, adhesion or other joining manners.

In some alternative embodiments, continuing to refer to FIGS. 1-3, the through holes 21 are provided in the main body, and more than four through holes 21 are distributed at intervals on an outer circumferential side of the groove. Preferably, the through hole 21 is formed in a shape of taper.

It should be understood that the number of the through holes 21 may be four, five, six, etc., and four through holes 21 are shown in the accompanying drawings. Optionally, a plurality of through holes 21 may be arranged at even intervals. As shown in FIG. 1, the through hole 21 may be formed in a shape of taper of which cross-sectional area gradually decreases from top to bottom, so as to facilitate the arrangement of the filling portion 31.

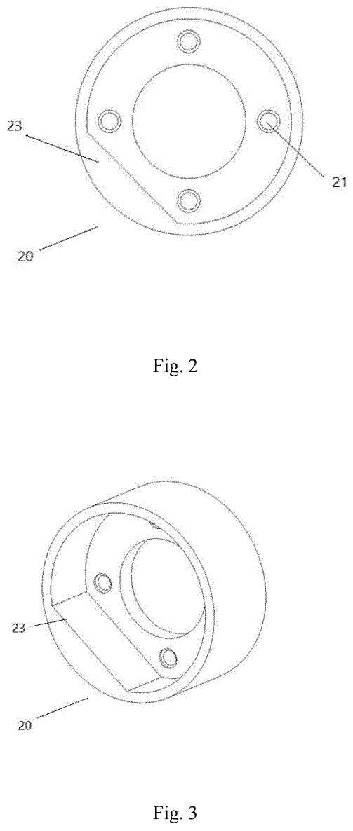

In some optional embodiments, as shown in FIGS. 2-4, the supporting portion 11 includes a notch 13 that is recessed from the outer surface toward inner surface of the supporting portion 11, and the extending portion 22 includes a protrusion 23 that matches the notch 13. It is understandable that the specific shapes of the notch 13 and the protrusion 23 are not limited, and when the sealing member 20 is sleeved on the sensitive chip 10, the notch 13 and the protrusion 23 engage with each other to prevent the sensitive chip 10 from rotating relative to the sealing member 20. Optionally, the notch 13 is a straight notch, the protrusion 23 is a straight protrusion, and the straight notch and the straight protrusion match each other.

In some optional embodiments, the supporting portion 11 includes a stepped structure protruding outwardly at one end away from the thin wall portion 12. Specifically, as shown in FIG. 1, the outer side wall of the lower end of the supporting portion 11 protrudes outwardly to form a step with a stepped surface.

In some alternative embodiments, the extending portion 22 abuts against the step and forms a seal. Specifically, the lower surface of the extending portion 22 faces the stepped surface of the supporting portion 11, and abuts against the stepped surface to form the seal. It can be understood that welding, bonding, adhesion, etc., and other sealing join manners known in the prior art can be used between the lower surface of the extending portion 22 and the stepped surface of the supporting portion 11.

In any of the above embodiments, the filling portion 31 is made of a conductive paste, the lead-out portion 32 is formed as a metal lead pin, and the filling portion 31 is electrically connected to the electrode. For example, the conductive paste (that is, the filling portion 31) before solidified may be a mixture of silver powder, epoxy resin and glass powder, a mixture of copper powder, epoxy resin and glass powder, or other components or mixtures of conductive pastes. The lead-out portion 32 may be made of a metal material such as copper and silver.

In any of the above embodiments, a base material of the sensitive chip 10 may be metal material (such as stainless steel), and the upper surface of the sensitive chip 10 (as shown in FIG. 1 and FIG. 5) is covered with an insulating layer 15, on which the electrode (the electrode 14 as shown) and a functional layer 16 are provided.

The functional layer 16 is disposed on the thin wall portion 12, and the functional layer 16 is formed as a Wheatstone bridge in an example; when there is a pressure change on the lower surface of the thin wall portion 12 (as shown in FIG. 1), the thin wall portion 12 will be deformed, causing that the arm resistance of the Wheatstone bridge (the functional layer 16) on the thin wall portion 12 changes, which in turn causes that the output of the Wheatstone bridge changes, thereby causing the electrical signal outputted via the electrode and the conductive member 30 to change, so as to achieve the pressure sensing.

In any of the above embodiments, the material of the sealing member 20 may be metal or non-metal. In the case that the sealing member 20 is made of the metal, an insulating layer is provided on the inner wall of the through hole 21, and optionally, the insulating layer may be a glass or ceramic material sintered on the inner wall of the through hole 21.

Below, a packaging method of a pressure sensor according to the embodiment of the present application will be described in detail with reference to FIGS. 1 to 6.

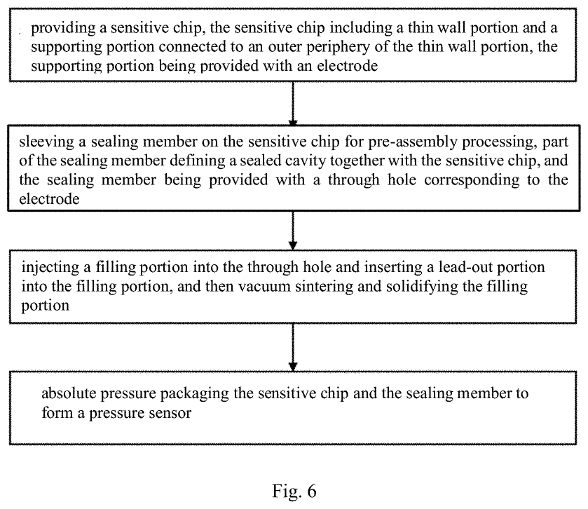

FIG. 6 is a flowchart of a packaging method of a pressure sensor provided by an embodiment of the present application, and the packaging method includes the following steps:

providing a sensitive chip 10, wherein the sensitive chip 10 includes a thin wall portion 12 and a supporting portion 11 connected to an outer periphery of the thin wall portion 12, the supporting portion 11 is provided with an electrode, and optionally, the thin wall portion 12 and the supporting portion 11 may be integrally formed;

sleeving a sealing member 20 on the sensitive chip 10 for pre-assembly processing, wherein part of the sealing member 20 defines a sealed cavity 40 together with the sensitive chip 10, and the sealing member 20 is provided with a through hole 21 corresponding to the electrode;

injecting a filling portion 31 into the through hole 21 and inserting a lead-out portion 32 into the filling portion 31, and then vacuum sintering and solidifying the filling portion 31; and

performing absolute pressure packaging of the sensitive chip 10 and the sealing member 20 to form a pressure sensor.

In the embodiment of the present application, the provided sealing member 20 is sleeved on the sensitive chip 10, a sealed cavity is formed between the thin wall portion 12 of the sensitive chip 10 and the sealing member 20, and the conductive member 30 disposed in the through hole 21 on the sealing member 20 is electrically connected to the electrode on the sensitive chip 10, wherein the filling portion 31 of the conductive member 30 is injected into the through hole 21 and the lead-out portion 32 of the conductive member 30 is inserted into the filling portion 31, and then the filling portion 31 is vacuumed sintered and solidified; in the packaging method of the pressure sensor, an electrical connection with the electrode is formed by means of the conductive member without using lead wires, which reduces the packaging size of the pressure sensor and realizes the absolute pressure packaging.

In some optional embodiments, the step of sleeving the sealing member 20 on the sensitive chip 10 for pre-assembly processing includes a step of: positioning a notch 13 on the sensitive chip 10 relative to a protrusion 23 on the sealing member 20 in an engagement manner for the pre-assembly processing. By positioning the notch 13 relative to the protrusion 23 in the engagement manner, the through hole 21 on the sealing member 20 can be aligned with the electrode on the sensitive chip 10 simply and conveniently during the pre-assembly process, thereby facilitating subsequent operations.

In some optional embodiments, the step of sealing the sensitive chip 10 and the sealing member 20 includes a step of: using an electron beam welding device in which gas in a chamber is replaced with dry argon, and welding and sealing the sensitive chip 10 with the sealing member 20 when a vacuum degree of the electron beam welding device is decreased below a predetermined value.

In another embodiment of the present application, a packaging method of a pressure sensor provided by an embodiment of the present disclosure includes the following steps of:

S10: providing a steel cup, a metal sealing member 20 and a metal lead-out portion 32;

S20: depositing an insulating layer, a functional layer, and an electrode layer on the steel cup in sequence, and obtaining a sensitive chip 10 with an electrode after photoetching, aging, and screening;

S30: providing a through hole 21 on the sealing member 20 and laying an insulating layer at the through hole 21, wherein the insulating layer may be a glass or ceramic layer sintered on the inner wall of the through hole 21;

S40: performing a pre-assembly processing on the sensitive chip 10 and the sealing member 20 and fixing them;

S50: injecting a filling portion 31 into the through hole 21 of the sealing member 20, and then inserting a lead-out portion 32 into the filling portion 31 and fixing it, and subsequently, vacuum sintering the filling portion 31, wherein alternatively, the filling portion 31 may be a mixture of silver powder, epoxy resin and glass powder, a mixture of copper powder, epoxy resin and glass powder, or components or mixtures of other conductive pastes;

S60: welding a welding interface between the sensitive chip 10 and the sealing member 20, wherein optionally, the welding interface may be a joint interface formed by joining the stepped surface of the sensitive chip 10 and the lower surface of the extending portion 22 of the sealing member 20 (as shown in FIG. 1).

In some optional embodiments, the step S10 includes steps of:

S11: preparing the steel cup, the metal sealing member 20 and the metal lead-out portion 32 by mechanical processing;

S12: washing the steel cup, the sealing member 20 and the lead-out portion 32; and

S13: grinding and polishing the steel cup.

In some optional embodiments, the step S40 includes steps of:

S41: positioning a notch 13 on the sensitive chip 10 relative to a protrusion 23 on the sealing member 20 in an engagement manner to achieve the pre-assembly;

S42: performing circumferential spot welding on the welding interface between the sensitive chip 10 and the sealing member 20 for fixing. Optionally, the number of welding spots in the spot welding process is 3 to 10, with the fusion penetration no more than 0.2 mm, and the positions of the welding spots are required to be evenly distributed in the circumferential direction.

In some optional embodiments, the step S60 includes steps of:

S61: replacing the gas in the chamber of the electron beam welding device with dry argon, to reduce the water vapor content in the chamber;

S62: decreasing the vacuum degree of the electron beam welding device below a required value, wherein optionally, the required value is 1 kPa; and

S63: using the electron beam welding device to weld the welding interface to form an absolute pressure packaging structure.

The embodiment of the present application provides a packaging method of a pressure sensor, in which there is no need to reserve operating space for joining process of the electrode of the sensitive chip 10 and the conductive paste, and the packaging structure has a diameter consistent with that of the sensitive chip 10, thereby reducing the diameter of the packaging structure of the pressure sensor; since the packaging structure of the pressure sensor does not require an adapting plate, the height of the packaging can be reduced by 5 mm to 10 mm. Moreover, since the packaging structure of the pressure sensor does not include lead wires, there is no risk of lead wire breakage even in extreme shock and vibration environments, thereby enhancing the adaptability of the sensor in harsh environments.

Although the present application has been described with reference to the preferred embodiments, various modifications can be made to them without departing from the scope of the present application, and the components therein can be replaced with equivalents. In particular, as long as there is no structural conflict, the various technical features mentioned in the various embodiments can be combined in any manner. The present application is not limited to the specific embodiments disclosed in the text, but includes all technical solutions falling within the scope of the claims.

1. A pressure sensor, comprising:
a sensitive chip, comprising a thin wall portion and a supporting portion connected to an outer periphery of the thin wall portion, and the supporting portion being provided with an electrode;
a sealing member, sleeved on the sensitive chip, part of the sealing member defining a sealed cavity together with the sensitive chip, and the sealing member being provided with a through hole corresponding to the electrode;
a conductive member, disposed in the through hole in a sealing manner and electrically connected with the electrode, and the conductive member being insulated from the sealing member, wherein the conductive member comprises a filling portion and a lead-out portion embedded in the filling portion.

2. The pressure sensor according to claim 1, wherein the sealing member comprises a main body and an extending portion connected to the main body, and the main body and the extending portion form an accommodating cavity together, the sealing member is sleeved on the sensitive chip through the accommodating cavity, and the extending portion covers an outer surface of the supporting portion;
the main body is provided with a groove, the groove faces the accommodating cavity, and the thin wall portion covers an opening of the groove to form the sealed cavity.

3. The pressure sensor according to claim 2, wherein the through hole is provided in the main body, and more than four through holes are distributed at intervals on an outer circumferential side of the groove;
the through hole is formed in a shape of taper.

4. The pressure sensor according to claim 1, wherein the supporting portion includes a notch recessed from an outer surface toward an inner surface of the supporting portion, and the extending portion includes a protrusion that matches the notch.

5. The pressure sensor according to claim 1, wherein the supporting portion includes a stepped structure protruding outwardly at an end away from the thin wall portion.

6. The pressure sensor according to claim 5, wherein the extending portion abuts against the stepped structure and forms a seal.

7. The pressure sensor according to claim 1, wherein the filling portion is made of a conductive paste, the lead-out portion is formed as a metal lead pin, and the filling portion is electrically connected with the electrode.

8. A packaging method of a pressure sensor, wherein the method comprises the following steps of:
providing a sensitive chip, the sensitive chip comprising a thin wall portion and a supporting portion connected to an outer periphery of the thin wall portion, the supporting portion being provided with an electrode;
sleeving a sealing member on the sensitive chip for pre-assembly processing, part of the sealing member defining a sealed cavity together with the sensitive chip, and the sealing member being provided with a through hole corresponding to the electrode;
injecting a filling portion into the through hole and inserting a lead-out portion into the filling portion, and then vacuum sintering and solidifying the filling portion; and
absolute pressure packaging the sensitive chip and the sealing member to form a pressure sensor.

9. The packaging method of a pressure sensor according to claim 8, wherein the step of sleeving the sealing member on the sensitive chip for pre-assembly processing comprises a step of: positioning a notch on the sensitive chip relative to a protrusion on the sealing member in an engagement manner for pre-assembly processing.

10. The packaging method of a pressure sensor according to claim 8, wherein the step of absolute pressure packaging the sensitive chip and the sealing member comprises a step of: using an electron beam welding device in which gas in a chamber is replaced with dry argon, and welding and sealing the sensitive chip and the sealing member when a vacuum degree of the electron beam welding device is decreased below a predetermined value.
